(19) United States
(12) Patent Application Publication
(10) Pub. No.: US 2016/0293886 A1
(43) Pub. Date: Oct. 6, 2016

(54) ORGANIC LIGHT-EMITTING DIODE (OLED) DISPLAY PANEL AND MANUFACTURING METHOD THEREOF

(71) Applicant: BOE TECHNOLOGY GROUP CO., LTD., Beijing (CN)

(72) Inventors: Donghui YU, Beijing (CN); Chun Jan WANG, Beijing (CN); Wenfeng SONG, Beijing (CN)

(73) Assignee: BOE TECHNOLOGY GROUP CO., LTD., Beijing (CN)

(21) Appl. No.: 14/769,323

(22) PCT Filed: Oct. 15, 2014
(86) PCT No.: PCT/CN2014/088692

§ 371 Date: Aug. 20, 2015

(30) Foreign Application Priority Data
Jul. 21, 2014 (CN) 201410347239.6

(51) Int. Cl. H01L 51/52; H01L 27/32; H01L 51/56

(52) U.S. Cl. CPC H01L 51/5256; H01L 51/56; H01L 27/32

(57) ABSTRACT

An organic light-emitting diode (OLED) display panel and a manufacturing method thereof are disclosed. The manufacturing method includes: providing a first substrate (1) and a second substrate (2), in which the first substrate (1) is provided with an OLED layer (3); coating a first sealant (4) on a surface of the OLED layer (3) of the first substrate (1); coating a second sealant (5) on a surface of the second substrate (2) and coating a third sealant (6) outside the second sealant (2) on the second substrate (2), in which the first sealant (4) has a viscosity less than that of the second sealant (5); and pressing the first substrate (1) and the second substrate (2) together and performing curing to allow the second sealant (5) to cover the first sealant(4) and fill a gap among the first substrate (1), the second substrate (2) and the third sealant (6). The manufacturing method can reduce the tension of a contact surface between the sealant and an OLED in the curing process, reduce the damage to the OLED, and ensure that a sealing structure of the OLED has good water resistance.

### TECHNICAL FIELD

Embodiments of the present invention relate to a method for manufacturing an organic light-emitting diode (OLED) display panel and the OLED display panel.

### BACKGROUND

OLED display panel has become new-generation display technology due to the advantages of self-luminous property, wide viewing angle, high contrast, rapid response speed, etc. The basic structure of an OLED generally comprises: a substrate, a first electrode layer, a second electrode layer, a light emitting layer (EML) and a cover. An organic functional layer on the substrate is sealed by the cover and a sealant so as to avoid the deterioration of the device performances and the service life due to the external environment (water, oxygen).

A sealant in contact with the OLED is generally required to have low viscosity and high water resistance simultaneously, so that good package property can be guaranteed without damaging devices. However, low viscosity and high water resistance are actually conflictive in general and it is difficult for one sealing material to have the above two properties at the same time.

### SUMMARY

At least one embodiment of the present invention provides an OLED display panel and a manufacturing method thereof, which can ensure that a package structure of an OLED has good package property without damaging devices.

At least one embodiment of the present invention provides a method for manufacturing an OLED display panel. The method comprises: providing a first substrate and a second substrate, in which the first substrate is provided with an OLED layer; coating a first sealant on a surface of the OLED layer so as to cover the surface of the OLED layer; coating a second sealant on a surface of the second substrate and coating a third sealant outside the second sealant on the surface of the second substrate, in which the first sealant has a viscosity less than that of the second sealant; and pressing the first substrate and the second substrate together and performing curing to allow the second sealant to cover the first sealant and fill a gap among the first substrate, the second substrate and the third sealant.

At least one embodiment of the present invention further provides an OLED display panel, which comprises: a first substrate and a second substrate arranged opposite to each other; an OLED layer formed on the first substrate; a first sealant coated on a surface of the OLED layer; a second sealant coated on a surface of the second substrate; and a third sealant coated outside the second sealant on the surface of the second substrate. The first sealant has a viscosity less than that of the second sealant; the second sealant covers the first sealant and fills a gap among the first substrate, the second substrate and the third sealant; and the third sealant seals the second sealant.

### BRIEF DESCRIPTION OF THE DRAWINGS

Simple description will be given below to the accompanying drawings of the embodiments to provide a more clear understanding of the technical solutions of the embodiments of the present invention. Obviously, the drawings described below only involve some embodiments of the present invention but are not intended to limit the present invention.

FIG. 1 is a schematic diagram of a method for manufacturing an OLED display panel according to an embodiment of the present invention;

FIG. 2 is a schematic diagram illustrating a sealing process of an OLED display panel according to an embodiment of the present invention; and

FIG. 3 is a schematic structural view of an OLED display panel according to an embodiment of the present invention.

Reference numerals of the accompanying drawings:

### 1—First Substrate; 2—Second Substrate; 3—OLED Layer; 4—First Sealant; 5—Second Sealant; 6—Third Sealant. DETAILED DESCRIPTION

For more clear understanding of the objectives, technical solutions and advantages of the embodiments of the present invention, clear and complete description will be given below to the technical solutions of the embodiments of the present invention with reference to the accompanying drawings of the embodiments of the present invention. Obviously, the preferred embodiments are only part of the embodiments of the present invention but not all the embodiments. All the other embodiments obtained by those skilled in the art without creative efforts on the basis of the embodiments of the present invention illustrated shall fall within the scope of protection of the present invention.

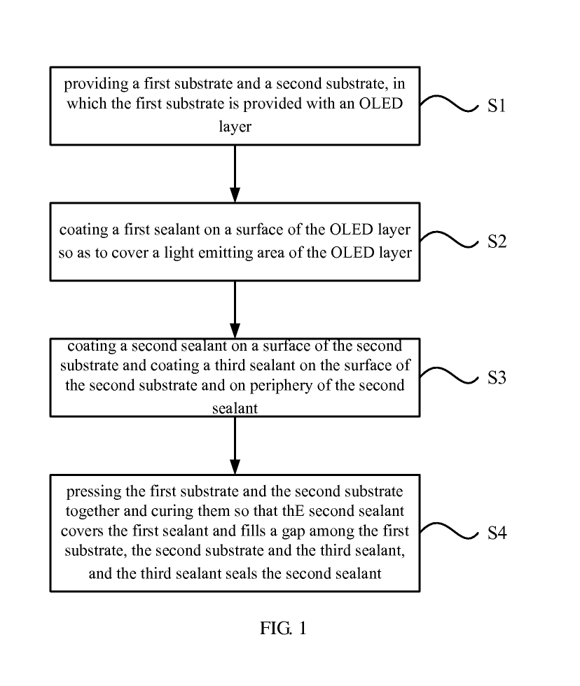

FIG. 1 is a schematic diagram of a method for manufacturing an OLED display panel according to an embodiment of the present invention.

As illustrated in FIG. 1, a method for manufacturing the OLED display panel according to at least one embodiment of the present invention comprises: step S1: providing a first substrate and a second substrate, in which the first substrate is provided with an OLED layer; step S2: coating a first sealant on a surface of the OLED layer so as to cover the surface of the OLED layer; step S3: coating a second sealant on a surface of the second substrate and coating a third sealant outside the second sealant on the surface of the second substrate, in which the first sealant has a viscosity less than that of the second sealant; and step S4: pressing the first substrate and the second substrate together and performing curing to allow the second sealant to cover the first sealant and fill a gap among the first substrate, the second substrate and the third sealant.

It should be noted that: the steps S2 and S3 have no sequence limitation and may be executed simultaneously or sequentially no matter which is performed first; and meanwhile, the coating of the second sealant and the coating of the third sealant also have no sequence limitation and may be performed simultaneously or sequentially no matter which is performed first. In addition, the method for manufacturing the OLED display panel may further comprise other processes which may be achieved by the prior art and are not directly relevant to the technical solutions in the above embodiments. No further description will need to be given here.

In at least one embodiment of the present invention, the first sealant is a sealing material with a viscosity of 10 cp to 20 cp, and the second sealant is a water-resistant or water-absorbing material with a viscosity of more than 50 cp.

For instance, the first sealant comprises at least one selected from the group consisting of polyolefin material, olefinic alcohol material and polyester material.

For instance, the second sealant comprises at least one selected from the group consisting of glass cement material, UV glue material, acrylic resin material and epoxy resin material.

Ultra-low viscosity materials such as polyolefin material, olefinic alcohol material or polyester material are taken as a sealant directly contacting the OLED layer. Compared with the case that high-viscosity materials directly contact the OLED layer, the ultra-low viscosity materials can ensure that the tension produced on a contact surface between the sealant and the OLED layer in the curing process is low, and hence can greatly reduce the damage to the OLED layer.

Moreover, the case that a high-viscosity sealant is adopted to cover periphery of the first sealant can ensure that a sealing structure has good water-resistant or water-absorbing property and prevents external moisture from passing through the second sealant, so that the first sealant keeps the OLED layer sealed and at the same time is not permeated by the external moisture. Moreover, the third sealant is adopted to seal the second sealant, so that the sealing structure can obtain better protection and ensure that the second sealant maintains good surface uniformity.

In at least one embodiment, the coating thickness of the first sealant is 6 nm to 20 nm. The first sealant within the above thickness range can maintain good surface uniformity in the pressing and curing process, and hence good sealability can be guaranteed.

For instance, the first sealant may be coated on the surface of the OLED by slit-coating.

For instance, the second sealant and/or the third sealant may be coated on the second substrate by die-coating. The above method is more convenient in coating the second sealant and the third sealant on the second substrate.

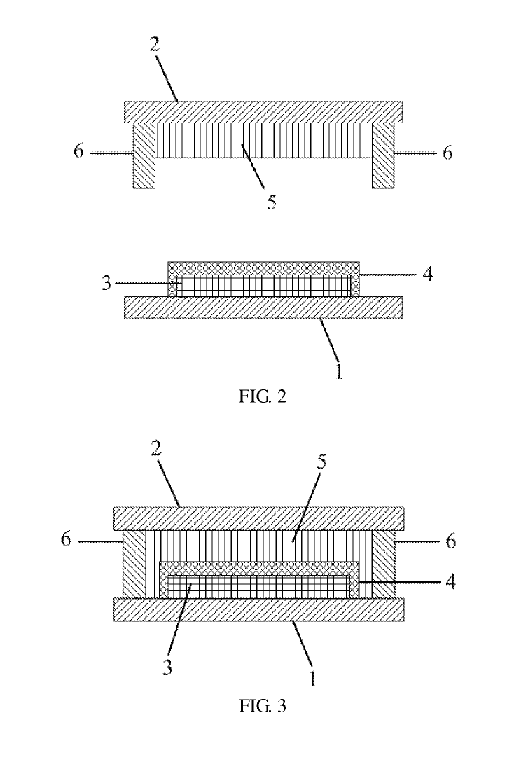

FIG. 2 is a schematic diagram illustrating a sealing process of an OLED display panel according to an embodiment of the present invention.

As illustrated in FIG. 2, an OLED layer 3 is disposed on a first substrate 1; a second substrate 2 is equivalent to a cover; in one aspect, a first sealant 4 is coated on the OLED layer 3 by, for instance, slit-coating; in another aspect, a second sealant 5 is coated on the second substrate 2 by, for instance, die-coating, and a third sealant 6 is coated on outside of the second sealant 5; subsequently, the second substrate 2 and the first substrate 1 are pressed together under vacuum environment to allow the second sealant 5 to fill a gap formed among the first substrate 1, the second substrate 2 and the third sealant 6 and cover the first sealant 4, and allow the third sealant 6 to seal the second sealant 5; and finally, a complete sealing structure is formed by light-curing or thermo-curing.

For instance, the OLED layer 3 may include an organic functional layer structure, for instance, sequentially superimposed an anode, a light-emitting structure and a cathode, or sequentially superimposed a cathode, a light-emitting structure and an anode. The light-emitting structure may include a hole transport layer (HTL), an light emitting layer (EML), an electron transport layer (ETL), etc.

FIG. 3 is a schematic structural view of an OLED display panel according to an embodiment of the present invention.

As illustrated in FIG. 3, the sealing structure of the OLED display panel provided by the embodiment of the present invention includes a first substrate 1 and a second substrate 2 arranged opposite to each other. The first substrate 1 is provided with an OLED layer 3; a first sealant 4 is coated on a surface of the OLED layer 3 on the first substrate 1 and configured to cover a luminous region of the OLED layer 3 and is a sealing material with a viscosity of 10 cp to 20 cp; a second sealant 5 is coated on a surface of the second substrate and is a water-resistant or water-absorbing material with a viscosity of more than 50 cp; and a third sealant 6 is coated outside the second sealant 5 on the second substrate 2. The first substrate 1 and the second substrate 2 are arranged opposite to each other and pressed together and cured under vacuum to allow the second sealant 5 to cover the first sealant 4 and fill a gap among the first substrate 1, the second substrate 2 and the third sealant 6, and allow the third sealant 6 to seal the second sealant 5.

For instance, the first sealant 4 comprises at least one selected from the group consisting of polyolefin material, olefinic alcohol material or polyester material.

For instance, the second sealant 5 includes an epoxy resin material.

Ultra-low viscosity materials such as polyolefin material, olefinic alcohol material or polyester material are taken as a sealant and directly contact the OLED layer 3. Compared with the case that high-viscosity materials directly contact the OLED layer, the ultra-low viscosity materials can ensure that the tension produced on a contact surface between the sealant and the OLED layer 3 in the curing process is low, and hence can greatly reduce the damage to the OLED layer 3.

Moreover, the case that high-viscosity sealant is adopted to cover outside of the first sealant 4 can ensure that the sealing structure has good water resistance. Furthermore, the third sealant 6 is adopted to seal the second sealant 5, so that the sealing structure can obtain better protection and ensure that the second sealant 5 maintains good surface uniformity.

By adoption of the above technical solutions, the adopted sealant for package is divided into three types. A first sealant having a low viscosity is adopted to contact the OLED, so that the tension on a contact surface between the sealant and the OLED in the curing process can be reduced, and hence the damage to the OLED can be minimized Moreover, a second sealant having high-viscosity is adopted to cover the first sealant, so that the sealing structure of the OLED can be guaranteed to have good water-resistant or water-absorbing properties at the same time. Furthermore, the third sealant is adopted to seal the second sealant, so that the sealing structure can obtain good protection and ensure that the second sealant maintain good surface uniformity.

The OLED display panel provided by at least one embodiment of the present invention comprises: a first substrate and a second substrate arranged opposite to each other; an OLED layer formed on the first substrate; a first sealant coated on a surface of the OLED layer; a second sealant coated on a surface of the second substrate; and a third sealant coated outside the second sealant on the surface of the second substrate. The viscosity of the first sealant is less than that of the second sealant; the second sealant covers the first sealant and fills a gap among the first substrate, the second substrate and the third sealant; and the third sealant seals the second sealant.

It should be noted that: in the present application document, the terms “first”, “second” and “third” are only used for distinguishing and should not be understood as an indication or implication of a relative importance. In addition, it should be known by those skilled in the art that the OLED display panel according to the embodiments of the present invention may further comprise other structures and components according to practical demands and the method for manufacturing the OLED display panel may further comprise other steps and details which may adopt the prior art, so no further description will need to be given here.

The foregoing is only the preferred embodiments of the present invention and not intended to limit the scope of protection of the present invention. The scope of protection of the present invention should be defined by the appended claims.

The application claims priority to the Chinese patent application No. 201410347239.6, filed on Jul. 21, 2014, the disclosure of which is incorporated herein by reference as part of the application.

1. A method for manufacturing an organic light-emitting diode (OLED) display panel, comprising:
providing a first substrate and a second substrate, in which the first substrate is provided with an OLED layer;
coating a first sealant on a surface of the OLED layer so as to cover a surface of the OLED layer;
coating a second sealant on a surface of the second substrate, and coating a third sealant outside the second sealant on the surface of the second substrate, in which the first sealant has a viscosity less than that of the second sealant; and
pressing the first substrate and the second substrate together and performing curing to allow the second sealant to cover the first sealant and fill a gap among the first substrate, the second substrate and the third sealant.

2. The method for manufacturing the OLED display panel according to claim 1, wherein the first sealant is a sealing material with a viscosity of 10 cp to 20 cp; and the second sealant is a water-resistant or water-absorbing material with a viscosity of more than 50 cp.

3. The method for manufacturing the OLED display panel according to claim 2, wherein the first sealant comprises at least one selected from the group consisting of polyolefin material, olefinic alcohol material and polyester material.

4. The method for manufacturing the OLED display panel according to claim 2, wherein the second sealant comprises at least one selected from the group consisting of glass cement material, UV glue material, acrylic resin material and epoxy resin material.

5. The method for manufacturing the OLED display panel according to claim 1, wherein the first sealant has a coating thickness of 6 μm to 20 μm.

6. The method for manufacturing the OLED display panel according to claim 1, wherein the first sealant is coated on the OLED layer by slit-coating.

7. The method for manufacturing the OLED display panel according to claim 1, wherein the second sealant and/or the third sealant is coated on the second substrate by die-coating.

8. An organic light-emitting diode (OLED) display panel, comprising:
a first substrate and a second substrate arranged opposite to each other;
an OLED layer formed on the first substrate;
a first sealant coated on a surface of the OLED layer;
a second sealant coated on a surface of the second substrate; and
a third sealant coated outside the second sealant on the surface of the second substrate, wherein
the first sealant has a viscosity less than that of the second sealant; the second sealant covers the first sealant and fills a gap among the first substrate, the second substrate and the third sealant; and the third sealant seals the second sealant.

9. The OLED display panel according to claim 8, wherein the first sealant is a sealing material with a viscosity of 10 cp to 20 cp; and the second sealant is a water-resistant or water-absorbing material with a viscosity of more than 50 cp.

10. The OLED display panel according to claim 9, wherein the first sealant comprises at least one selected from the group consisting of polyolefin material, olefinic alcohol material and polyester material.

11. The OLED display panel according to claim 9, wherein the second sealant comprises at least one selected from the group consisting of glass cement material, UV glue material, acrylic resin material and epoxy resin material.

12. The OLED display panel according to claim 8, wherein the first sealant has a coating thickness of 6 μm to 20 μm.

13. The OLED display panel according to claim 9, wherein the first sealant has a coating thickness of 6 μm to 20 μm.

14. The OLED display panel according to claim 10, wherein the first sealant has a coating thickness of 6 μm to 20 μm.

15. The OLED display panel according to claim 11, wherein the first sealant has a coating thickness of 6 μm to 20 μm.

16. The method for manufacturing the OLED display panel according to claim 2, wherein the first sealant is coated on the OLED layer by slit-coating.

17. The method for manufacturing the OLED display panel according to claim 3, wherein the first sealant is coated on the OLED layer by slit-coating.

18. The method for manufacturing the OLED display panel according to claim 2, wherein the second sealant and/or the third sealant is coated on the second substrate by die-coating.

19. The method for manufacturing the OLED display panel according to claim 3, wherein the second sealant and/or the third sealant is coated on the second substrate by die-coating.
